(19) United States
(12) Patent Application Publication
(10) Pub. No.: US 2026/0255713 A1
(43) Pub. Date: Aug. 27, 2026

(54) IMAGE SENSOR

(71) Applicant: SAMSUNG ELECTRONICS CO., LTD., Suwon-si (KR)

(72) Inventor: Kooktae KIM, Suwon-si (KR)

(73) Assignee: SAMSUNG ELECTRONICS CO., LTD., Suwon-si (KR)

(21) Appl. No.: 19/530,868

(22) Filed: Feb. 5, 2026

(30) Foreign Application Priority Data
Feb. 21, 2025 (KR) 10-2025-0022893

(51) Int. Cl. H10F 39/00

(52) U.S. Cl. CPC H10F 39/807

(57) ABSTRACT

Provided is an image sensor, including a substrate including pixel regions that include photoelectric conversion regions, respectively, a floating diffusion region in a pixel region of the pixel regions, the floating diffusion region being configured to store charge transmitted from a photoelectric conversion region among the photoelectric conversion regions and being on a first surface of the substrate, an element isolation region on the first surface of the substrate and adjacent to the floating diffusion region, and a conductive structure protruding in a vertical direction from a first surface of the element isolation region and a first surface of the floating diffusion region toward a second surface of the element isolation region and a second surface of the floating diffusion region, and contacting the floating diffusion region and the element isolation region.

### CROSS-REFERENCE TO RELATED APPLICATION

This application claims priority to Korean Patent Application No. 10-2025-0022893 filed on February 21, 2025, in the Korean Intellectual Property Office, the disclosure of which is incorporated herein by reference in its entirety.

### BACKGROUND

Embodiments of the present disclosure relate to an image sensor.

An image sensor is a semiconductor-based sensor configured to receive light and to generate an electrical signal, and may include a pixel array having a plurality of pixels, and a logic circuit for driving the pixel array and generating an image. Each pixel may include a photodiode and a pixel circuit converting charges generated by the photodiode into an electrical signal. As the number of pixels included in the image sensor increases and the size of each pixel decreases, various methods have been proposed to effectively form components disposed in respective pixels to provide a pixel circuit, and contact plugs and interconnection lines.

### SUMMARY

One or more embodiments provide an image sensor including an expansion portion for forming a conductive structure in a buried arrangement of burying an element isolation region, between a floating diffusion region and a contact plug, and bonding the conductive structure to the floating diffusion region.

According to an aspect of one or more embodiments, there is provided an image sensor, including a substrate including pixel regions that include photoelectric conversion regions, respectively, a floating diffusion region in a pixel region of the pixel regions, the floating diffusion region being configured to store charge transmitted from a photoelectric conversion region among the photoelectric conversion regions and being on a first surface of the substrate, an element isolation region on the first surface of the substrate and adjacent to the floating diffusion region, and a conductive structure protruding in a vertical direction from a first surface of the element isolation region and a first surface of the floating diffusion region toward a second surface of the element isolation region and a second surface of the floating diffusion region, and contacting the floating diffusion region and the element isolation region.

According to another aspect of one or more embodiments, there is provided an image sensor, including a substrate including pixel regions that include photoelectric conversion regions, respectively, a trench isolation region defining the pixel regions within the substrate, a floating diffusion region adjacent to the trench isolation region in a pixel region of the pixel regions, the floating diffusion region being configured to store charges transmitted from the photoelectric conversion region and being on a first surface of the substrate, an element isolation region on the trench isolation region that is on the first surface of the substrate and in contact with the floating diffusion region, and a conductive structure expanded from the element isolation region, and in contact with at least two floating diffusion regions in two adjacent pixel regions of the pixel regions, wherein a first surface of the conductive structure is coplanar with a first surface of the element isolation region and protrudes in a vertical direction into the element isolation region and the at least two floating diffusion regions.

According to still another aspect of one or more embodiments, there is provided an image sensor, including, a pixel array including a plurality of pixel regions on a first surface of a substrate, a pixel region of the plurality of pixel regions including a photodiode and a color filter on a second surface of the substrate, opposite to the first surface, and a logic circuit configured to obtain a pixel signal from the plurality of pixel regions, wherein the pixel array includes a floating diffusion region in a pixel region of the plurality of pixel regions, the floating diffusion region being configured to store charges transmitted from the photodiode and being on the first surface of the substrate, an element isolation region adjacent to the floating diffusion region, and a conductive structure protruding in a vertical direction from a first surface of the element isolation region and a first surface of the floating diffusion region toward a second surface of the element isolation region and a second surface of the floating diffusion region, and contacting the floating diffusion region and the element isolation region.

According to further still another aspect of one or more embodiments, there is provided a method of manufacturing an image sensor including forming a trench isolation film defining pixel regions and an element isolation region from a first surface of the substrate on the trench isolation film, within a substrate, forming a first opening by etching at least a portion of the element isolation region and a second opening by etching the first surface of the substrate adjacent to the first opening, on the first surface of the substrate, forming a conductive structure by filling a conductive material in the first opening and the second opening, and forming a floating diffusion region on the first surface of the substrate to overlap at least a portion of the conductive structure;

In the forming the conductive structure, the conductive material may be buried so as to include a first region protruding in a vertical direction from a first surface of the element isolation region, and a second region filling the second opening to protrude in a horizontal direction from a side surface of the first region.

The method further includes flattening the conductive material so that a first surface of the first region and an upper surface of the second region are coplanar.

A first length from the upper surface of the first region to a second surface may be greater than a second length from the first surface of the second region to a second surface.

The forming the floating diffusion region may include doping a first conductivity impurity to have a third length, from a first surface to a second surface, which is greater than the first length.

The forming the conductive structure may include stacking a semiconductor material with the conductive material.

The floating diffusion region may include the first conductive impurity in a first concentration, and the conductive structure may include the first conductive impurity in a second concentration, greater than the first concentration.

The method of manufacturing an image sensor may further include forming a contact plug electrically connected to the floating diffusion region, and the contact plug may contact a first surface of the first region of the conductive structure.

The contact plug may be formed to be spaced apart from the second region of the conductive structure.

The conductive structure may be formed to connect at least two adjacent floating diffusion regions.

### BRIEF DESCRIPTION OF DRAWINGS

The above and other aspects, features, and advantages of the present disclosure will be more clearly understood from the following detailed description, taken in conjunction with the accompanying drawings, in which:

FIG. 1 is a block diagram illustrating an image sensor according to one or more embodiments;

FIG. 2 is a circuit diagram illustrating a pixel circuit according to one or more embodiments;

FIG. 3 is a view illustrating an arrangement of pixels of the image sensor of FIG. 2;

FIG. 4 is a cross-sectional view illustrating the image sensor of FIG. 3;

FIG. 5 is an enlarged view of a portion of FIG. 4;

FIGS. 6, 7, 8, 9 and 10 are enlarged views of an image sensor according to one or more embodiments;

FIGS. 11, 12, and 13 are layout views of an image sensor according to one or more embodiments;

FIG. 14 is a cross-sectional view of an image sensor according to one or more embodiments; and

FIGS. 15A, 15B, 15C, 15D, 15E, 15F, 15G, 15H, 15I, 15J, 15K, 15L, 15M, 15N, 15O, 15P, 15Q and 15R are cross-sectional views illustrating a method of manufacturing the image sensor of FIG. 4.

### DETAILED DESCRIPTION

Hereinafter, embodiments of the present disclosure will be described with reference to the accompanying drawings. Embodiments described herein are example embodiments, and thus, the disclosure is not limited thereto.

It will be understood that, although the terms first, second, third, fourth, etc. may be used herein to describe various elements, components, regions, layers and/or sections (collectively “elements”), these elements should not be limited by these terms. These terms are only used to distinguish one element from another element. Thus, a first element described in this description section may be termed a second element or vice versa in the claim section without departing from the teachings of the disclosure.

It will be understood that when an element or layer is referred to as being “over,” “above,” “on,” “below,” “under,” “beneath,” “connected to” or “coupled to” another element or layer, it can be directly over, above, on, below, under, beneath, connected or coupled to the other element or layer or intervening elements or layers may be present. In contrast, when an element is referred to as being “directly over,” “directly above,” “directly on,” “directly below,” “directly under,” “directly beneath,” “directly connected to” or “directly coupled to” another element or layer, there are no intervening elements or layers present.

As used herein, an expression “at least one of” preceding a list of elements modifies the entire list of the elements and does not modify the individual elements of the list. For example, an expression, “at least one of a, b, and c” should be understood as including only a, only b, only c, both a and b, both a and c, both b and c, or all of a, b, and c. As used herein, the term “and/or” includes any and all combinations of one or more of the associated listed items.

Herein, a direction parallel to a main surface (upper surface or lower surface) of a substrate 101 may be referred to as a horizontal direction (X direction and/or Y direction), and a direction perpendicular and normal to the horizontal direction (X direction and/or Y direction) may be referred to as a vertical direction (Z direction).

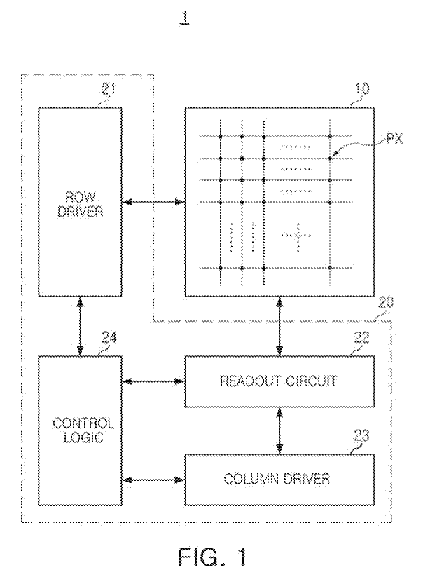

FIG. 1 is a block diagram illustrating an image sensor according to one or more embodiments.

Referring to FIG. 1, an image sensor 1 may include a pixel array 10 and a logic circuit 20.

The pixel array 10 may include a plurality of pixels PX disposed in an array form along a plurality of rows and a plurality of columns. Each of the plurality of pixels PX may include at least one photoelectric conversion element configured to generate charges in response to light, and a pixel circuit configured to generate a pixel signal corresponding to the charges generated by the photoelectric conversion element. The photoelectric conversion element may include a photodiode formed of a semiconductor material, and/or an organic photodiode formed of an organic material.

For example, the pixel circuit may include a floating diffusion, a transfer transistor, a reset transistor, a driving transistor, and a selection transistor. The configuration of the pixels PX may vary depending on embodiments. For example, each of the pixels PX may include an organic photodiode including an organic material, or may be implemented as a digital pixel. When the pixels PX are implemented as the digital pixels, each of the pixels PX may include an analog-to-digital converter for outputting a digital pixel signal.

The logic circuit 20 may include circuits for controlling the pixel array 10. For example, the logic circuit 20 may include a row driver 21, a readout circuit 22, a column driver 23, and a control logic 24. The row driver 21 may drive the pixel array 10 in units of row lines. For example, the row driver 21 may generate a transmission control signal for controlling a transfer transistor of the pixel circuit, a reset control signal for controlling a reset transistor, a selection control signal for controlling a selection transistor, and may input such signals to the pixel array 10 in units of row lines.

The readout circuit 22 may include a correlated double sampler (CDS) and an analog-to-digital converter (ADC). The correlated double samplers may be connected through the pixels PX and the column lines. The correlated double samplers may read the pixel signal from the pixels PX connected to a row line selected by a row line selection signal of the row driver 21 through the column lines. The analog-to-digital converter may convert the pixel signal detected by the correlated double sampler into a digital pixel signal and transmit the pixel signal to the column driver 23.

The column driver 23 may include a latch or buffer circuit and an amplifier circuit that may temporarily store the digital pixel signal, and may process a digital pixel signal received from the readout circuit 22. The row driver 21, the readout circuit 22 and the column driver 23 may be controlled by the control logic 24. The control logic 24 may include a timing controller for controlling the operation timing of the row driver 21, the readout circuit 22, and the column driver 23.

Among the pixels PX, pixels PX disposed in the same position in the horizontal direction may share the same column line. For example, pixels PX disposed in the same position in the vertical direction may be simultaneously selected by the row driver 21 and may output pixel signals through the column lines. In one or more embodiments, the readout circuit 22 may simultaneously obtain pixel signals from pixels PX selected by the row driver 21 through the column lines. The pixel signal may include a reset voltage and a pixel voltage, and the pixel voltage may be a voltage in which charges generated in response to light in each of the pixels PX are reflected in the reset voltage.

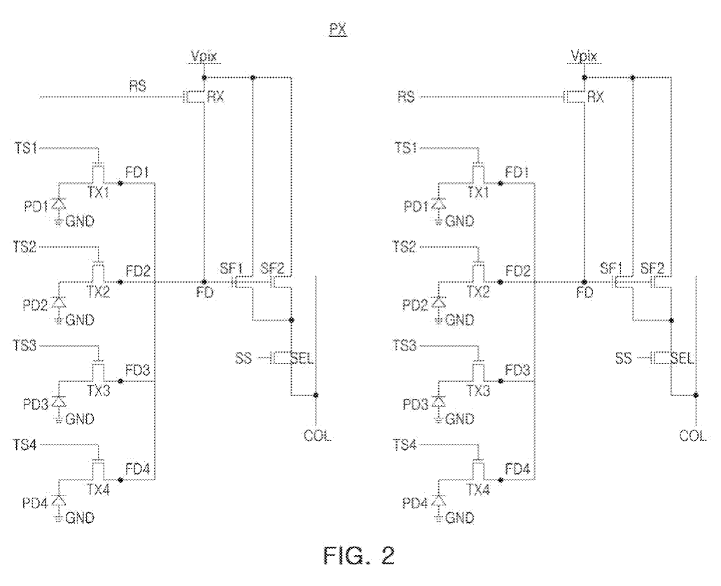

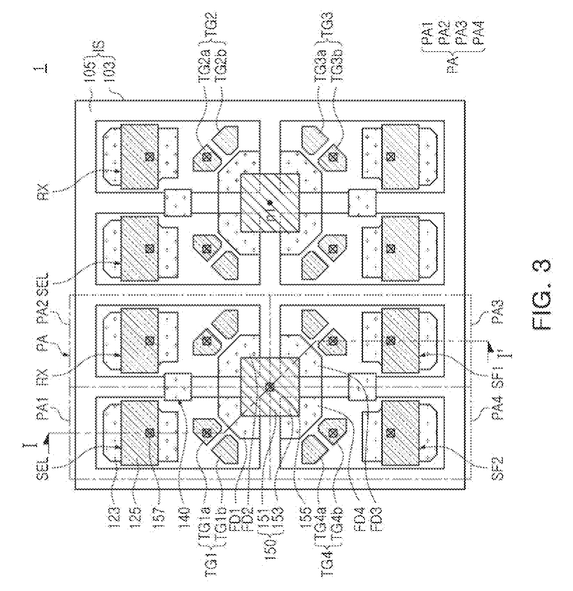

FIG. 2 is a circuit diagram illustrating a pixel circuit according to one or more embodiments, and FIG. 3 is a view illustrating an arrangement of pixels of the image sensor of FIG. 2.

Referring to FIG. 2, each of the plurality of pixels PX (see FIG. 1) may include a photoelectric conversion element and a pixel circuit, and the pixel circuit may include a transfer transistor TX, a reset transistor RX, a selection transistor SEL, and a source follower transistor SF. Additionally, the pixel circuit may further include a floating diffusion region FD in which charges generated by the photoelectric conversion element are accumulated. Hereinafter, the photoelectric conversion element will be described as a photodiode PD, which is an example of the photoelectric conversion element.

The photodiode PD may generate and accumulate charges in response to externally incident light. The photodiode PD may be replaced with a phototransistor, a photogate, a pinned photodiode, or the like, according to one or more embodiments.

The transfer transistor TX may be turned on or off by a transmission control signal input to a transfer gate TG. The transfer transistor TX may move the charge generated by the photodiode PD to the floating diffusion region FD. The floating diffusion region FD may store the charges generated by the photodiode PD. A voltage output by the source follower transistor SF may vary depending on the amount of charges accumulated in the floating diffusion region FD.

The reset transistor RX may receive a reset signal RS and reset the voltage of the floating diffusion region FD by removing the charges accumulated in the floating diffusion region FD. A drain electrode of the reset transistor RX may be connected to the floating diffusion region FD and the source electrode may be connected to a power supply voltage Vpix. When the reset transistor RX is turned on, the power supply voltage Vpix connected to a source electrode of the reset transistor RX is applied to the floating diffusion region FD, and the reset transistor RX may remove the charges accumulated in the floating diffusion region FD.

The source follower transistor SF may operate as a source follower buffer amplifier. The source follower transistor SF may amplify a voltage change of the floating diffusion region FD and output the same to column lines COL.

The selection transistor SEL may select pixels PX to be read in a column unit among a plurality of pixels PX. When the selection transistor SEL is turned on, a voltage of the source follower transistor SF may be output to the column lines COL. For example, when the selection transistor SEL is turned on, a reset voltage or pixel voltage may be output through the column lines COL.

The reset transistor RX may be controlled by a reset control signal RG, and the selection transistor SEL may be controlled by a selection control signal SS. A first transfer transistor TX1, a second transfer transistor TX2, a third transfer transistor TX3, and a fourth transfer transistor TX4 may be controlled by the first or second bias voltage, which is transmission signals TS1, TS2, TS3, and TS4.

Each of the pixels PX may be structured as one pixel region PA, each pixel region PA may further include a ground region GND that may receive a ground voltage. Accordingly, each pixel region PA may include a ground region GND, a photodiode PD, a transfer transistor TX, a reset transistor RX, a selection transistor SEL, and a source follower transistor SF.

Each of the pixels PX may be structured as one pixel region PA, and one pixel region PA may include four sub-pixel regions including a first sub-pixel region PA1, a second sub-pixel region PA2, a third sub-pixel region PA3, and a fourth sub-pixel region PA4, as illustrated in FIG. 3. The four sub-pixel regions PA1 to PA4 may be arranged in a 2X2 array. The first sub-pixel region PA1 may include a ground region GND, a first photodiode PD1, a first floating diffusion region FD1, and a first transfer transistor TX1 having a first transfer gate TG1. In the first pixel region PA1, the first photodiode PD1 may be connected to the first floating diffusion region FD1 via the first transfer transistor TX1. Similarly, a second photodiode PD2, a third photodiode PD3, and a fourth photodiode PD4 of the second to fourth sub-pixel regions PA2 to PA4 may be connected to a second floating diffusion region FD2, a third floating diffusion region FD3, and a fourth floating diffusion region FD4 via the a second transfer transistor TX2, a third transfer transistor TX3, and a fourth transfer transistor TX4 respectively including a second transfer gate TG2, a third transfer gate TG3, and a fourth transfer gate TG4.

In four adjacent sub-pixel regions PA1 to PA4, the first to fourth floating diffusion regions FD1 to FD4 may be connected to each other by a conductive structure 150 to operate as one floating diffusion region FD, and the first to fourth transfer gates TG1, TG2, TG3, and TG4 may be commonly connected to one floating diffusion region FD connecting the first to fourth floating diffusion regions FD1 to FD4 to each other.

Four adjacent sub-pixel regions PA1 to PA4 may share a pixel circuit, and the shared pixel circuit may include the reset transistor RX, a first source follower transistor SF1, a second source follower transistor SF2, and a selection transistor SEL.

For example, each of the four sub-pixel regions PA1 to PA4 may include one more transistor in addition to the transfer transistor TX. Two of the four transistors included in the four sub-pixel regions PA1 to PA4 may be connected in parallel to each other to be configured as the first and second driving transistors SF1 and SF2, and one of the remaining two transistors may be configured as a selection transistor SEL and the other thereof may be configured to provide a reset transistor RX.

The pixel circuit described with reference to FIG. 2 is an example embodiment and embodiments are not limited thereto. For example, one of the four transistors may be assigned as a source follower transistor SF, and one may be assigned as a selection transistor SEL, and the other may be assigned as a reset transistor RX. Additionally, the remaining one may be assigned as a dual conversion gain transistor DCX connected in series to the reset transistor RX to implement an image sensor 1 capable of controlling the conversion gain of the pixel. As another example, the pixel circuit may vary depending on the number of transistors included in each of the pixels PX.

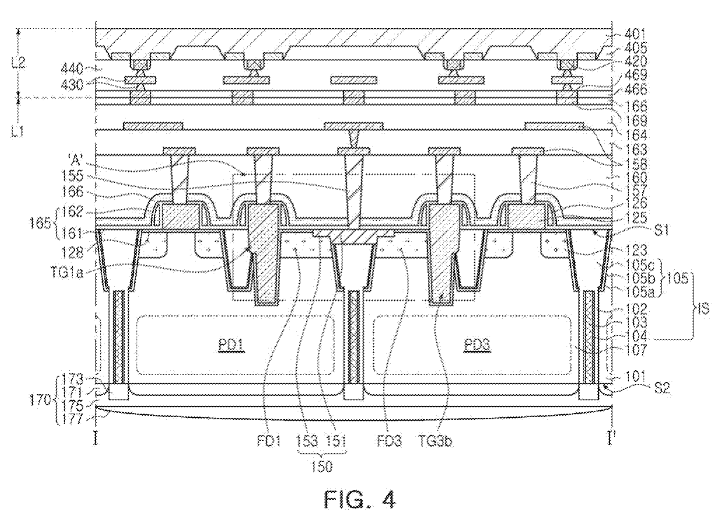

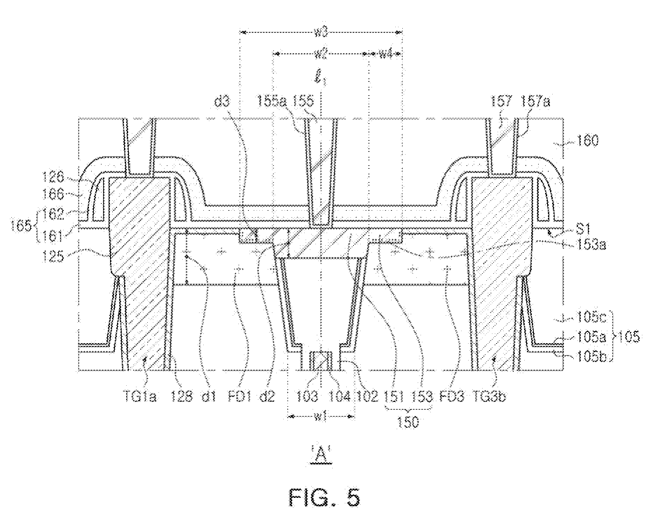

The pixels PX of FIG. 2 may be implemented as unit pixel regions PA having the same arrangement as FIG. 3. FIG. 3 is a view illustrating the pixels of the image sensor 1 of FIG. 2, and FIG. 4 is a cross-sectional view illustrating a cross-section of one of the pixels of FIG. 3. FIG. 4 is a cross-sectional view taken along Ⅰ-Ⅰ’ of FIG. 3, and FIG. 5 is an enlarged view of region ‘A’ of FIG. 4. In FIG. 3, the image sensor 1 is a top plan view of a region corresponding to two pixels PX of a pixel array 10 on a substrate 101.

The image sensor 1 may include a first structure L1 corresponding to the pixel array 10 and a second structure L2 corresponding to a logic circuit 20 bonded thereto.

The pixel regions PA corresponding to the pixels PX in the pixel array 10 include 2x2 sub-pixel regions PA1 to PA4. The pixel regions PA or sub-pixel regions PA1 to PA4 may include all of the photodiodes PD1 to PD4, active regions 123 and ground regions GND 140 included in the substrate 101, and the pixel region PA may be defined as a region in which elements for operating as one pixel PX of FIG. 2 are disposed, and the sub-pixel regions PA1 to PA4 may be defined as regions partitioned by a trench separator 103 within the pixel region PA.

Accordingly, the trench separator 103 is disposed between the sub-pixel regions PA1 to PA4 and between the pixel regions PA. The trench separator 103 may be arranged in a grid shape within the substrate 101, and each of the sub-pixel regions PA1 to PA4 may include a polygon, for example, a square and a rectangle, when viewed from the top, and the pixel region PA may be implemented as a polygon, particularly, a square, preferably a rectangle or a square, including four sub-pixel regions PA1 to PA4.

The first to fourth sub-pixel regions PA1 to PA4 may have substantially the same area (size) and/or same shape, and the elements may be arranged symmetrically with respect to a center n1 of the pixel region PA.

Each of the first to fourth sub-pixel regions PAb to PA4 may include one transistor, at least one transfer gate TG1 to TG4, and one floating diffusion region FD1, FD2, FD3 or FD4. A ground region GND may be disposed in contact with at least a portion of each sub-pixel region PA1 to PA4.

The first to fourth floating diffusion regions FD1, FD2, FD3 and FD4 within the first to fourth sub-pixel regions PA1 to PA4 may be regions doped with first conductive impurities, and may be regions in which charges generated by the photodiodes PD1 to PD4 are accumulated. For example, the first conductive impurity may be an N-type impurity. The first conductive impurity may be arsenic (As) or phosphorus (P,) and may satisfy a first concentration, for example, 1x10¹⁶ to 1x10¹⁸/cm³.

The first to fourth floating diffusion regions FD1, FD2, FD3 and FD4 may be electrically connected to at least one contact plug 150, and the first to fourth floating diffusion regions FD1, FD2, FD3 and FD4 may be adjacent to the first to fourth transfer gates TG1 to TG4, respectively. The transfer gates TG1 to TG4 may be adjacent to the first to fourth photodiodes PD1 to PD4 formed on an inner side of the trench isolation film 103 in a first direction (Z-direction).

When a first bias voltage is input to the first to fourth transfer gates TG1 to TG4, charges generated by the first to fourth photodiodes PD1 to PD4 may not move to the first to fourth floating diffusion regions FD1, FD2, FD3 and FD4. When the voltage of the first to fourth transfer gates TG1 to TG4 increases to a second bias voltage greater than the first bias voltage, charges generated by the first to fourth photodiodes PD1 to PD4 may move to the first to fourth floating diffusion regions FD1, FD2, FD3 and FD4. For example, the first bias voltage may be a negative voltage, and the second bias voltage may be a positive voltage. An absolute value of the first bias voltage may be smaller than an absolute value of the second bias voltage.

In FIG. 3, the first to fourth floating diffusion regions FD1, FD2, FD3 and FD4 may be disposed adjacently to the center n1 of the pixel region PA, and a corner region in which four sub-pixel regions PA1 to PA4 meet. For example, the first to fourth floating diffusion regions FD1, FD2, FD3 and FD4 may extend to have an area extending from the center n1 of the pixel region PA in a second direction (X-direction) and/or a third direction (Y-axis direction). However, the shape of the first to fourth floating diffusion regions FD1, FD2, FD3 and FD4 is not limited to that illustrated in FIG. 3, and may be variously modified according to embodiments.

The first transfer gate TG1 of the first transfer transistor TX1 connected to the first photodiode PD1 may be disposed in the first sub-pixel region PA1, and the second transfer gate TG2 of the second transfer transistor TG2 connected to the second photodiode PD2 may be disposed in the second sub-pixel region PA2. In the third sub-pixel region PA3, the third transfer gate TG3 of the third transfer transistor TX1 connected to the third photodiode PD3 may be disposed, and in the fourth sub-pixel region PA4, the fourth transfer gate TG4 of the fourth transfer transistor TG4 connected to the fourth photodiode PD4 may be placed.

Among the transistors, one of the reset transistor RX, the selection transistor SEL, and the driving transistors DX1 and DX2 may be disposed in each of the first to fourth sub-pixel regions PA1 to PA4. For example, the selection transistor SEL may be disposed in the first sub-pixel region PA1, the reset transistor RX may be disposed in the second sub-pixel region PA2, and first and second driving transistors DX1 and DX2 may be disposed in the third and fourth sub-pixel regions PA3 and PA4, respectively.

Each of the transistors, which are circuit elements, may include gate structures 125 and 126, and active regions 123 arranged on both sides of the gate structures 125 and 126. An area of each of the active regions 123 may be smaller than an area of the first to fourth floating diffusion regions FD1, FD2, FD3 and FD4. This may be because the area of the floating diffusion regions FD1, FD2 and FD3 in which charges generated by respective photodiodes PD1 to PD4 are accumulated should be secured to be relatively larger. An element isolation region 105 for separating the active regions 123 may be further included.

An active region 140 for the ground region GND may be further included in the sub-pixel regions PA1 to PA4. The ground region GND may be separated from the floating diffusion regions FD1, FD2, FD3 and FD4 and the transistors, and may not be in contact with the transfer gates TG1 to TG4. Additionally, the ground region GND may be doped with an impurity of a second conductivity type, different from a conductivity type of the floating diffusion regions FD1, FD2, FD3 and FD4 and the active regions 123.

Contact plugs 155 and 157 may be disposed in the first to fourth transfer gates TG1 to TG4, the first to fourth floating diffusion regions FD1, FD2, FD3 and FD4, the gate structures 125 and 126, the active regions 123, and the ground region 140, and the first to fourth floating diffusion regions FD1, FD2, FD3 and FD4 may further include a conductive structure 150 for synthesizing four floating diffusion regions FD1, FD2, FD3 and FD4 in the center n1 of the pixel region PA to form one integrated floating diffusion region. The contact plugs 155 may not be directly disposed in the first to fourth floating diffusion regions FD1, FD2, FD3 and FD4, but may be electrically connected to the first to fourth floating diffusion regions FD1, FD2, FD3 and FD4 through the conductive structure 150.

The substrate 101 may be a semiconductor substrate. For example, the substrate 101 may be a substrate formed of a semiconductor material, for example, a single crystal silicon substrate. The substrate 101 may include one surface S1 on which the gate structures 125 and 126 of the circuit elements are disposed, and the active regions 123, the floating diffusion regions FD1, FD2, FD3 and FD4 and the element isolation region 105 are formed, and the other surface S2 opposite thereto.

Respective photodiodes PD1 to PD4 may be formed in the substrate 101 within the four sub-pixel regions PA1 to PA4. The photodiodes PD1 to PD4 include a first conductive type impurity, and may include, for example, an N-type impurity. The photodiodes PD1 to PD4 may be adjacent to each transfer gate TG in the Z-direction, perpendicular to a first surface S1 of the substrate 101.

An optical unit 170 may be disposed on a second surface S2 of the substrate 101, opposite to the first surface S1, adjacent to the photodiodes PD1 to PD4 in the Z-direction. The optical unit 170 may include a color filter 171, a grating structure 173, a planarization layer 175, and a microlens 177. The color filter 171 may be separated from the color filters of other adjacent pixels by the grating structure 173 and may transmit light of a predetermined wavelength band. The microlens 177 may refract light incident on a pixel 100 and may focus the light onto the photodiodes PD1 to PD4. The photodiodes PD1 to PD4 may generate charges in response to light passing through the optical unit 170.

Therefore, the optical unit 170 and circuit elements may be disposed on both sides of the photodiodes PD1 to PD4 in the Z-direction.

A trench separator 103 separating the photodiodes PD1 to PD4 within the substrate 101 and partitioning the sub-pixel regions PA1 to PA4 may be disposed in a grid shape within the substrate 101. The trench separator 103 may include a conductive material, for example, a semiconductor material, in a central region thereof, and may include a semiconductor material including an impurity of a second conductive type different from the first conductive type.

A liner 104 may be disposed to surround the conductive material, and a trench insulating layer 102 may be disposed between the liner 104 and the substrate 101. Accordingly, the conductive material in the trench separator 103 may be electrically insulated from the substrate 101. When the conductive material is included in the trench separator 103, the charge collection capability of the photodiodes PD1 to PD4 may be improved when a black current flows. A substrate insulating region 107 may be further included between the photodiodes PD1 to PD4 and the trench insulating layer 102, but embodiments are not limited thereto.

An element isolation region 105 (shallow trench isolation pattern (STI)) defining active regions 123 of circuit elements and floating diffusion regions FD1, FD2, FD3 and FD4 inside the substrate 101 may be disposed on the first surface S1 of the substrate 101.

The element isolation region 105 may be formed by removing all of the first surface S1 of the substrate 101 by a predetermined depth, excluding a region in which the active regions 123 of the circuit elements are disposed and a region in which the floating diffusion regions FD1, FD2, FD3 and FD4 are disposed, and then stacking an insulating material thereon.

The element isolation region 105 may also be disposed on the trench isolation film 103. As illustrated in FIG. 4, the element isolation region 105 may be aligned in the Z-direction on the trench isolation film 103 to form an isolation structure IS partitioning each sub-pixel region PA1 to PA4. The element isolation region 105 on the trench isolation film 103 may be disposed to have a width greater than a width of the trench isolation film 103, and may have a lower width W1 greater than an upper width of the trench isolation film 103.

An upper surface of the element isolation region 105 may be nearly coplanar with the first surface S1 of the substrate 101, but is not limited thereto, and may be coplanar with an upper surface of a gate insulating layer 128.

The element isolation region 105 may have a width in the X-direction and/or the Y-direction that decreases from an upper surface to a lower surface in the Z-direction, and may thus have an inclined side surface. The element isolation region 105 may include a liner 105b surrounding and/or adjacent to a side surface and a lower surface of the element isolation region 105, and an oxide film 105a disposed between the liner 105b and the substrate 101. A trench of the element isolation region 105 may be buried on the liner 105b and an insulating material 105c may be disposed. The insulating material 105c may be a material such as, for example, a silicon oxide film, a silicon nitride film, or a silicon oxynitride film. In this case, in the isolation structure IS in which the element isolation region 105 and the trench isolation film 103 extend in the Z-direction, the liner 105b may not be disposed on the lower surface of the element isolation region 105 in contact with an upper portion of the trench isolation film 103. When the element isolation region 105 is formed along the trench isolation film 103, the element isolation region 105 may include a grid shape and may also be disposed in the center n1 of the four sub-pixel regions PA1 to PA4, that is, in an intersection region in which the four floating diffusion regions FD1 to FD4 are disposed.

As illustrated in FIG. 5, the conductive structure 150 may be disposed inwardly and/or downwardly in the Z direction from the upper surface of the element isolation region 105 in the center n1 of the pixel region PA, into the element isolation region 105. The conductive structure 150 may be disposed while simultaneously filling and/or penetrating into a portion of at least one floating diffusion region FD1 to FD4 and a portion of the element isolation region 105 adjacent thereto.

The conductive structure 150 may protrude inwardly from the upper surface of the element isolation region 105 extending in a grid shape from the center n1 of the pixel region PA to the upper portion of the element isolation region 105, and may include a first region 151 having a second depth d2 in the Z-direction.

An upper surface of the first region 151 may be coplanar with an upper surface of the gate insulating layer 128 and an upper surface of another element isolation region 105, and a lower surface of the first region 151 may be disposed on a level that is higher than a lower surface of the element isolation region 105 in the Z-direction according to the second depth d2.

When the floating diffusion region FD1 to FD4 has a first depth d1 from the first surface S1 of the substrate 101 and the upper surface of the gate insulating layer 128, the second depth d2 of the first region 151 of the conductive structure 150 may be smaller than the first depth d1 and may satisfy 1/2 to 1/3 of the first depth d1 in the Z-direction. Accordingly, the first region 151 of the conductive structure 150 may have a shape that extends in a cross shape from the center n1 of the pixel region PA, i.e., a point of symmetry, and may be disposed at a substantially uniform second depth db within the element isolation region 105.

The conductive structure 150 may include second regions 153 protruding from a side surface of the first region 151 in the horizontal direction (X-direction and/or Y-direction) and expanded and/or penetrating into the floating diffusion region FD1 to FD4.

The second regions 153 may be disposed separately and/or spaced apart from each other and at least on one side of each of the second regions 153 may be connected to the first region 151.

When the first region 151 has a cross shape, the second regions 153 may fill in a space between arms of the cross shape to form the conductive structure 150 in a square shape on a plane. Accordingly, each of the second regions 153 may have a rectangular shape, but embodiments are not limited thereto.

Each of the second regions 153 may extend into each of the floating diffusion regions FDb to FD4, and may be formed by having a coplanar surface with the upper surface of another element isolation region 105, for example, the upper surface of the gate insulating layer 128, removing a portion of the floating diffusion region FD1 to FD4 from an upper surface thereof, and filling the removed space. Accordingly, the four second regions 153 around the first region 151 may be integrated with the first region 151 so that upper surfaces thereof have a coplanar surface.

The second regions 153 may have substantially the same area, but is not limited thereto, and the second regions 153 may extend from an upper surface thereof to the floating diffusion region FD1 to FD4 to have a third depth d3 in the Z direction. The third depth d3 may be smaller than the second depth d2, and may be 1/2 to 1/3 of the second depth d2.

Accordingly, the second regions 153, which are expansion portions, may be formed at a shallower depth than the first region 151 in the Z direction, thereby minimizing the influence on the floating diffusion regions FD1 to FD4, and achieving electrical and physical connection.

The conductive structure 150 may have, when viewed in a plan view, a second width W2 greater than the first width W1 of a lower portion of the element isolation region 105 in an upper portion of the first region 151 in the horizontal direction (X-direction and/or Y-direction). In this case, an upper portion of the conductive structure 150 may have a third width W3 greater than the second width W2 due to the expansion of the second regions 153.

Accordingly, the second region 153 may be disposed by a fourth width W4 equal to a difference between the second width W2 and the third width W3 to extend into the floating diffusion region FD1 to FD4 in the horizontal direction (X-direction and/or Y-direction).

The conductive structure 150 may include a conductive material and may include a semiconductor material, and may include a semiconductor material including a first conductive type impurity, such as polysilicon. For example, the conductive structure 150 may include an N-type impurity, and may include impurities such as, P and the like. In this case, the conductive structure 150 may include the same impurity as the impurity of the floating diffusion region FD1 to FD4, but is not limited thereto, and may include at least the same conductive type impurity as the impurity of the floating diffusion region FD1 to FD4.

In this case, a doping concentration of the impurity of the conductive structure 150 may have a second concentration, greater than the first concentration of the impurity of the floating diffusion region FD1 to FD4, and may satisfy, for example, 1xe¹⁸ to 1xe²¹/cm³, but embodiments are not limited thereto. When the conductive structure 150 includes a semiconductor material, the conductive structure 150 may have a crystal structure 153a having a single crystal, from a boundary between the second region 153, which is an extension portion, and the floating diffusion region FD1 to FD4. For example, crystallization may proceed from a single crystal structure of the silicon substrate 101 so that the conductive structure 150 may have a portion of the crystal structure 153a having the single crystal, and may have a polycrystalline crystal structure in the first region 151.

Accordingly, the conductive structure 150 may have a crystal structure similar to a crystal structure of the floating diffusion region FD1 to FD4 in a contact region with the floating diffusion region FD1 to FD4, thereby minimizing the contact resistance.

The conductive structure 150 may include metal materials having conductive properties, and for example, may include tungsten (W), titanium (Ti), copper (Cu), and aluminum (Al).

At least two, for example, four floating diffusion regions FD1 to FD4 separated from each other by the conductive structure 150 may be electrically and physically integrated, and may form one integrated floating diffusion region FD.

A substrate oxide layer 165 and a second upper insulating layer 166 may be disposed on the conductive structure 150, and an interlayer insulating layer 160 may be disposed on the substrate oxide layer 165 and the second upper insulating layer 166.

For electrical connection with the integrated floating diffusion region FD, the contact plug 155 may be disposed to be connected to an upper surface of the conductive structure 150 by penetrating through the substrate oxide layer 165, the second upper insulating layer 166, and the interlayer insulating layer 160.

The contact plug 155 may be disposed on the center n1 of the pixel region PA, i.e., the first region 151, and may be in contact with the first region 151, and may be physically separated from the second region 153.

The contact plugs 157 may be disposed in other contact regions, such as gate structures TG and 125, active regions 123, or ground regions 140, except for the contact plug 155 on the conductive structure 150.

The contact plugs 155 and 157 may be formed by having diffusion barriers 155a and 157a disposed on a side surface and a lower surface thereof, and burying a metal material in the diffusion barriers 155a and 157a.

The diffusion barriers 155a and 157a may be titanium nitride (TiN), tantalum nitride (TaN), and the like, and the contact plugs 155 and 157 may include a conductive material such as W, aluminum (Al), Cu, and the like.

Accordingly, since the diffusion barriers 155a and 157a are not directly connected to the floating diffusion region FD1 to FD4, when forming the contact plug 155, damage to the semiconductor substrate 101 may be minimized, and the number of contact plugs 155 may also be minimized.

The gate electrode 125 of the transistors may include a semiconductor material, for example, silicon (Si), germanium (Ge), or combinations thereof. The gate electrode 125 may include a layer doped with an N-type or a P-type, but may also include an undoped layer.

The transfer gate TG1 to TG4 may include at least one sub-transfer gate TG1a/TG1b, TG2a/TG2b, TG3a/TG3b and TG4a/TG4b that are separated from each other, and for example, as illustrated in FIG. 4, the transfer gate TG1 to TG4 may include two of sub-transfer gates TG1a/TG1b, TG2a/TG2b, TG3a/TG3b and TG4a/TG4b. Each of the sub-transfer gates TG1a/TG1b, TG2a/TG2b, TG3a/TG3b and TG4a/TG4b may have the same structure, but embodiments are not limited thereto. Each of the sub-transfer gates TG1a/TG1b, TG2a/TG2b, TG3a/TG3b and TG4a/TG4b may be disposed adjacent to the floating diffusion region FD1 to FD4 in the horizontal direction and may be connected in parallel. The sub-transfer gates TG1a/TG1b, TG2a/TG2b, TG3a/TG3b and TG4a/TG4b may include the same material as the gate electrode 125 of the circuit elements, and may be formed of a conductive material such as polysilicon, metal, or metal silicide, and a first bias voltage and a second bias voltage described above may be applied to the transfer gates TG1a/TG1b, TG2a/TG2b, TG3a/TG3b and TG4a/TG4b. The gate insulating layer 128, the gate spacer 126, and the like, may be disposed. The gate insulating layer 128 may be disposed between the transfer gates TG1a/TG1b, TG2a/TG2b, TG3a/TG3b and TG4a/TG4b and the substrate 101.

The transfer gates TG1a/TG1b, TG2a/TG2b, TG3a/TG3b and TG4a/TG4b may include a first electrode layer and a second electrode layer, and the first electrode layer and the second electrode layer may have different shapes. For example, the second electrode layer may be disposed between the first electrode layer and the photodiodes PD1 to PD4 in the Z-direction, and may have a width that becomes narrower as the second electrode layer is adjacent to the photodiodes PD1 to PD4. The second electrode layer may be disposed below one surface S1 of the substrate 101 and buried in the substrate 101, and the first electrode layer may have a region disposed above the first surface S1 of the substrate 101.

The gate insulating layer 128 may be formed along an interface between the transfer gates TG1a/TG1b, TG2a/TG2b, TG3a/TG3b and TG4a/TG4b and the substrate 101. The first electrode layer and the second electrode layer may be offset from each other in the horizontal direction and may be disposed in different positions. Accordingly, at least a portion of a lower surface of the first electrode layer may not be in direct contact with an upper surface of the second electrode layer, and at least a partial region of the gate insulating layer 128 may be disposed between the element isolation region 105 and the first electrode layer in the Z-direction.

The gate spacer 126 may be formed of silicon nitride or the like, and may be formed only around the first electrode layer.

The gate structures 125 and 126 of the transistors other than the transfer transistors TG1 and TG2 may have different shapes from the transfer gates TG1a/TG1b, TG2a/TG2b, TG3a/TG3b and TG4a/TG4b. As the gate structures 125 and 126 of the transistors are planar transistors, the gate structures 125 and 126 may be formed on a substrate 101, and may include a gate electrode 125, a gate insulating layer 128, and a gate spacer 126.

An insulating liner 161 and a plurality of upper insulating layers 162 and 166 may be included on one surface S1 of the substrate 101.

The insulating liner 161 may be conformally formed on the first surface S1 of the substrate 101. The insulating liner 161 may conformally cover and/or be provided on lower gates TG and 125 and the substrate 101 on the gates TG and 125. The insulating liner 161 may include silicon oxide or a low-κ dielectric material. The insulating liner 161 may extend with an insulating liner forming the gate insulating layer 128 disposed in lower portions of the gates TG and 125 and the insulating liners may be formed of the same material.

A first upper insulating layer 162 may be disposed on the insulating liner 161.

The first upper insulating layer 162 may be disposed to conformally cover and/or be provided on the gates TG, 125 and 126 of each circuit element, for example, the transfer gate TG, the reset gate electrode, the selection gate electrode, the spacers 126 of the driving gate electrodes 125, and the insulating liner 161 on the exposed substrate 101. The first upper insulating layer 162 may include a silicon oxide or a low-κ dielectric material as a protective film to insulate and protect the circuit elements in a lower portion from the outside.

The second upper insulating layer 166 may be disposed on the first upper insulating layer 162. The second upper insulating layer 166 may include a different material from the first upper insulating layer 162, and may conformally cover and/or be provided on the first upper insulating layer 162 over the circuit elements and the exposed substrate 101 so as to have a thickness greater than a thickness of the first upper insulating layer 162 in the Z-direction. The second upper insulating layer 166 may include a silicon nitride, a silicon oxynitride, or a low-κ dielectric material. The second upper insulating layer 166 may be formed of a different material from the first upper insulating layer 162, and thus the second upper insulating layer 166 may function as an etch-stop layer during the process.

The first upper insulating layer 162 and the second upper insulating layer 166 may have different functions, and the first upper insulating layer 162 and the second upper insulating layer 166 may include different materials, thereby protecting the lower circuit elements and the semiconductor substrate 101. A total thickness of the first upper insulating layer 162 and the second upper insulating layer 166 may be 30 to 50 nm, and may be 30 to 40 nm in the Z-direction. Additionally, the second upper insulating layer 166 may have the greatest thickness within the thickness, and a thickness of the insulating liner 161 may also be included within the total thickness. For example, the second upper insulating layer 166 may be the thickest, the insulating liner 161 may be the thinnest, and the first upper insulating layer 162 may have a thickness therebetween in the Z-direction.

The insulating liner 161 and the first upper insulating layer 162 may be collectively referred to as an oxide layer 165 including the same material, and may be implemented as silicon oxide layers formed by setting a deposition temperature differently during the process. Accordingly, crystal sizes thereof may be different from each other, but embodiments are not limited thereto.

An interlayer insulating layer 160 may be provided on the substrate 101. The interlayer insulating layer 160 may cover and/or be provided on the gate electrodes 125 of the transfer gate TG, the selection transistor SEL, the reset transistor RX and the driving transistors DX1 and DX2 on the second upper insulating layer 166 and an exposed substrate 101 therebetween. The interlayer insulating layer 160 may include a single film or a multi-film structure of at least one of a silicon oxide film (SiO), a silicon nitride film (SiN), a silicon oxynitride film (SiON), and a porous low-κ dielectric film.

Intermetal insulating layers 163 and 164 may be provided on the interlayer insulating layer 160. The intermetal insulating layers 163 and 164 may include a single film or a multi-film structure of at least one of a silicon oxide film (SiO), a silicon nitride film (SiN), a silicon oxynitride film (SiON), and a porous insulating film. Upper interconnection lines 158 and contact vias may be disposed between the intermetallic insulating layers 163 and 164. The contact vias may include a metal such as tungsten (W), aluminum (Al), or copper (Cu), and tungsten may be preferably applied thereto.

The contact vias may have a pillar shape and may have an inclined side surface in which a width thereof decreases toward a substrate 301.

The first structure L1 may include first bonding structures 166 and 169.

The first bonding structures 166 and 169 may include a first bonding insulating layer 166 and first bonding pads 169, and may perform hybrid bonding with the second bonding structure of the second structure L2.

The second structure L2 may include a logic substrate 401, and may include a second interconnection structure 430 connected to second circuit elements 420, a second bonding structure 440 on the second interconnection structure 430, and a logic insulating layer 443 covering and/or being provided on the second circuit elements 420 and the second interconnection structure 430 on the logic substrate 401. The second bonding structures 466 and 469 may be connected to the second interconnection structure 430 on the second interconnection structure 430. The second bonding structures 466 and 469 may include a metal material such as copper (Cu). The second bonding structures 466 and 469 may include a bonding pad 469, may be physically bonded to the first bonding pads 169, and may provide an electrical connection path. The second bonding insulating layer 466 may be bonded to the first bonding insulating layer 166 to provide a hybrid bond. The logic insulating layer 440 may cover and be provided on the second circuit elements 420 and the third interconnection structure 430.

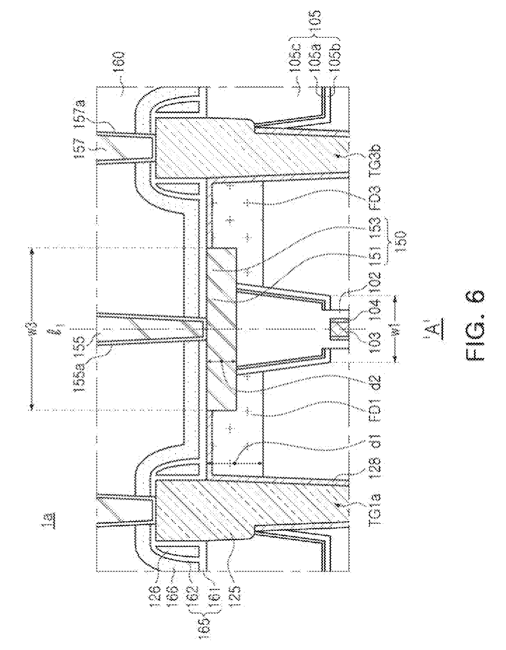

Hereinafter, one or more embodiments of the present disclosure will be described with reference to FIGS. 6 to 10. FIGS. 6 to 10 are enlarged views of region “A” of FIG. 5 according to one or more other embodiments.

Referring to FIG. 6, an image sensor 1a of one or more embodiments may be the same as the image sensor of FIG. 5, except for the shape of the conductive structure 150.

For example, the conductive structure 150 may include a first region 151 and a second region 153. The first region 151 may be disposed by being buried in the element isolation region 105 from the first surface S1 of the substrate 101, and a first side of the second region 153 may be connected to the first region 151 and the second region 153 and disposed by being buried in the floating diffusion region FD1 to FD4 from the first region 151.

For example, on a plane, arrangements of the first region 151 and the second region 153 may be the same as in FIG. 3.

In this case, a depth of the first region 151 and a depth of the second region 153 may be the same as each other in the Z-direction, and may be disposed to have a substantially uniform third width W3 in the horizontal direction (X-direction and/or Y-direction) from an upper surface to a lower surface. That is, the conductive structure 150 may be disposed to have a flat lower surface without a bent portion or a stepped portion on a lower surface.

Accordingly, the conductive structure 150 may have a uniform second depth d2 in the Z-direction, and the second depth d2 may be smaller than the first depth d1 of the floating diffusion region FD1 to FD4.

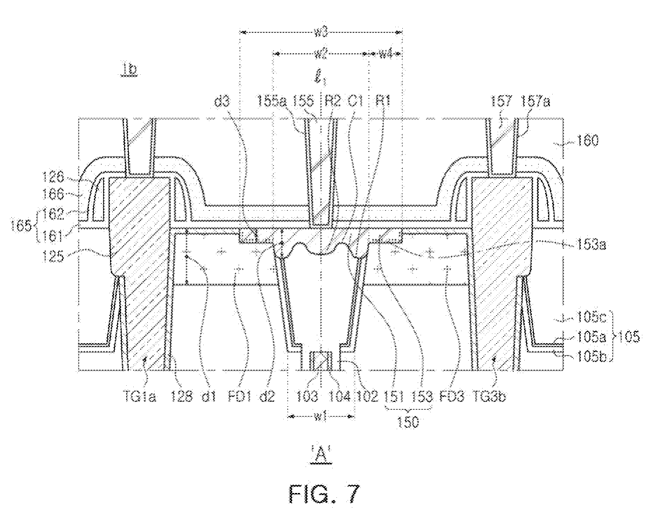

Referring to FIG. 7, an image sensor 1b of one or more embodiments may be the same as the image sensor of FIG. 5, except for the shape of the conductive structure 150.

For example, the conductive structure 150 may include a first region 151 and a second region 153. The first region 151 may be disposed by being buried in the element isolation region 105 from the first surface S1 of the substrate 101, and the first side of the second region 153 may be connected to the first region 151 and the second region 153 may be disposed by being buried in the floating diffusion region FD1 to FD4 from the first region 151.

The second region 153 may have a third depth d3 in the Z-direction, which may be smaller than the first depth d1 of the floating diffusion region FD1 to FD4.

The first region 151 may have an upper surface coplanar with an upper surface of the second region 153, and may be coplanar with an upper surface of the substrate 101 and the upper surface of the gate insulating layer 128. A lower surface of the first region 151 may have a bent portion. For example, a lower surface of the first region 151 may have a low level to form a valley R1 at a boundary between the element isolation region 105 and the floating diffusion region FD1 to FD4, may have a peak C1 by protruding toward an upper surface of the element isolation region 105, and may have a valley R2 in a central region thereof. A level of the valley R2 of the central region may be disposed higher than a level of the valley R1 of the boundary in the Z-direction. According to a bent shape of a lower surface thereof, the first region 151 may have different depths in the Z-direction. For example, the valley R1 of the boundary may have a second depth d2, and the valley R2 of the central portion may have a depth smaller than the second depth d2, but may have a depth larger than the third depth d3. The bent portion may be generated when the liner 105a, which is a nitride of the boundary, is over-etched due to a difference in etching speed between the liner 105b and the oxide film 105a, during the etching of the element isolation region 105 for forming the conductive structure 150. Additionally, as the central region may be over-etched depending on a density difference of the oxide film 105c, the valley R2 of the central region may be formed.

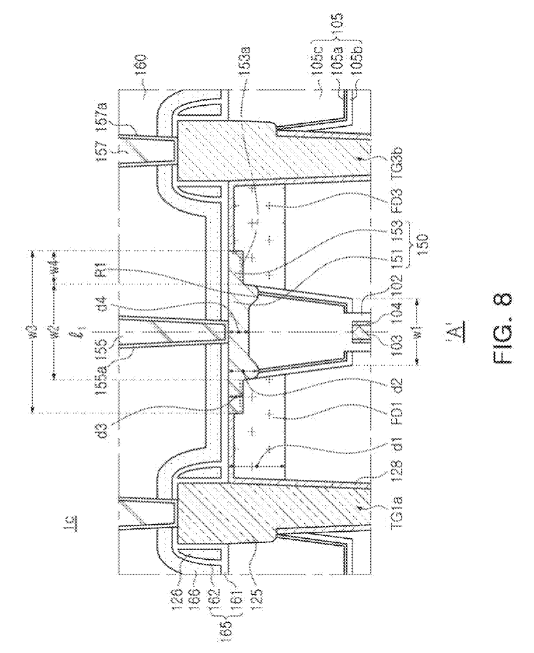

Referring to FIG. 8, an image sensor 1c of one or more embodiments may be the same as the image sensor of FIG. 5, except for the shape of the conductive structure 150.

For example, the conductive structure 150 may include a first region 151 and a second region 153. The first region 151 may be disposed by being buried in the element isolation region 105 from the first surface S1 of the substrate 101, and the first side of the second region 153 may be connected to the first region 151 and the second region 153 may be disposed by being buried in the floating diffusion region FD1 to FD4 from the first region 151.

The second region 153 may have a third depth d3, and may be smaller than the first depth d1 of the floating diffusion region FD1 to FD4 in the Z-direction.

The first region 151 may have an upper surface coplanar with the upper surface of the second region 153 and may be coplanar with the upper surface of the gate insulating layer 128 of the substrate 101. A lower surface of the first region 151 may have a bent portion. For example, the lower surface of the first region 151 may have a low level to form a valley R1 at a boundary between the element isolation region 105 and the floating diffusion region FD1 to FD4, and a region other than the boundary may protrude toward an upper surface of the element isolation region 15.

Depending on the bent shape of the lower surface, the first region 151 may have different depths in the Z-direction. For example, a valley R1 of the boundary may have a second depth d2, and a central region may have a fourth depth d4 smaller than the second depth d2, but the fourth depth d4 may be larger than the third depth d3. The bent portion may be generated when the liner 105b, which is a nitride at the boundary, is over-etched due to a difference in etching speed between the liner 105b and the oxide film 105a, during the etching of the element isolation region 105 for forming the conductive structure 150,

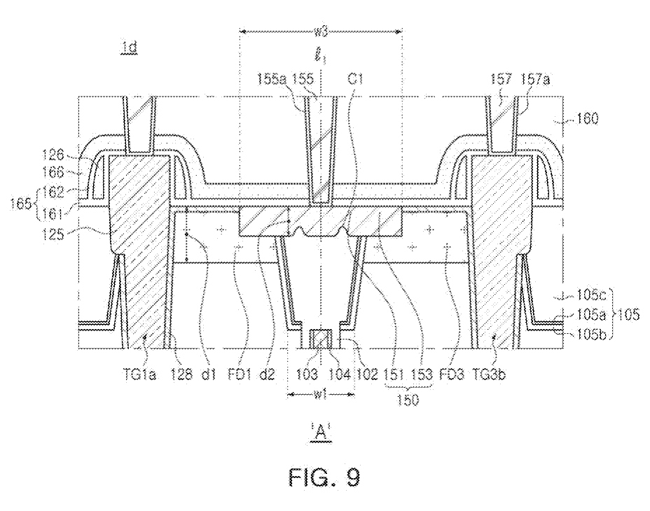

Referring to FIG. 9, an image sensor of one or more embodiments may be the same as an image sensor 1d of FIG. 5, except for the shape of the conductive structure 150.

For example, the conductive structure 150 may include a first region 151 and a second region 153. The first region 151 may be disposed by being buried in the element isolation region 105 from the first surface S1 of the substrate 101, and the first side of the second region 153 may be connected to the first region 151 and the second region 153 may be disposed by being buried in the floating diffusion region FD1 to FD4 from the first region 151.

The second region 153 may have a third depth d3, and may be smaller than the first depth d1 of the floating diffusion region FD1 to FD4 in the Z-direction.

The first region 151 may have an upper surface coplanar with the upper surface of the second region 153, and a lower surface of the first region 151 may have a bent portion. For example, the lower surface of the first region 151 may include a protruding region C1 protruding toward an upper surface from a boundary between the element isolation region 105 and the floating diffusion region FD1 to FD4 to a central region.

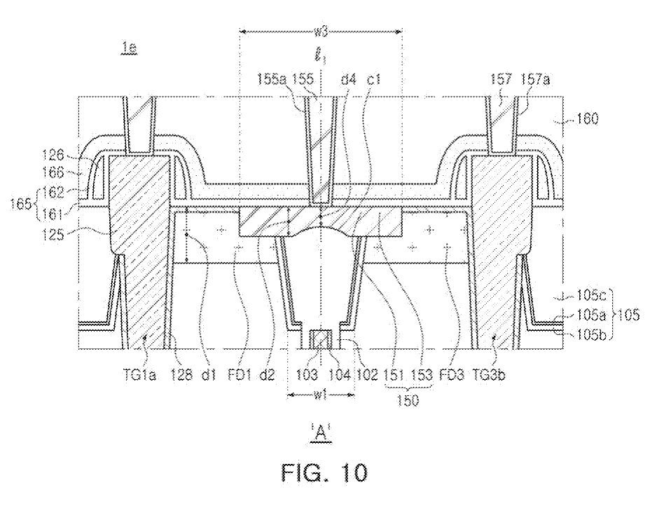

Referring to FIG. 10, the image sensor of one or more embodiments may be the same as an image sensor 1e of FIG. 5, except for the shape of the conductive structure 150.

For example, the conductive structure 150 may have the same depth in the first region 151 and the second region 153 in the Z-direction, and the lower surface of the first region 151 may be formed to have a convex curve C1 toward the upper surface in the central region. In this case, a maximum depth of the first region 151 may be the same as the third depth d3, and a minimum depth may satisfy the fourth depth d4 that is smaller than the third depth d3 in the central region.

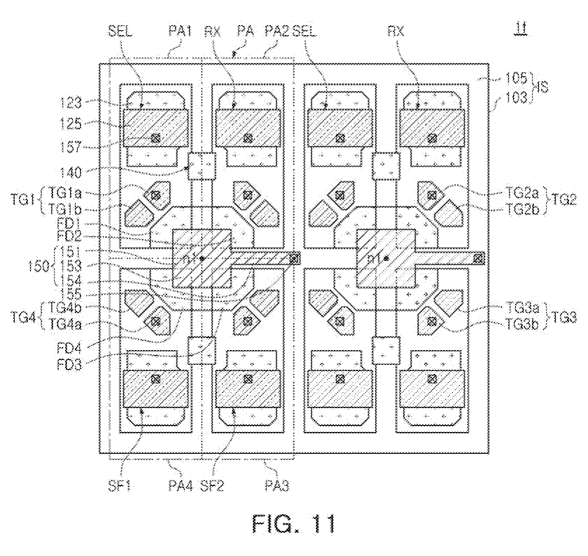

FIGS. 11 to 13 are cross-sectional views illustrating a plane of an image sensor according to one or more other embodiments. FIGS. 11 to 13 may be understood as illustrating a plane of a pixel region of the image sensor of FIG. 3.

Referring to FIG. 11, an image sensor 1f is the same as FIGS. 3 to 5, except for the shape of the conductive structure 150.

The conductive structure 150 of the image sensor 1f of FIG. 11 may include a first region 151 and a second region 153, and may further include a third region 154 extending from the first region 151 in the horizontal direction (X-direction or Y-direction) within the element isolation region 105.

The third region 154 may extend along the element isolation region 105 from a portion of the side surface of the first region 151 that does not contact the second region 153, and may extend, for example, in the X-direction, for example. In this case, the third region 154 may extend to an intersection n1 of the element separation region 105 and may extend in a bar shape. A width in a Y-direction, which is perpendicular to a longitudinal direction of the third region 154, may be smaller than a width of the element separation region 105. Accordingly, the third region 154 may have a width smaller than the second width W2 of the first region 151 in the Y-direction.

The contact plug 155 may be disposed in at least a portion of the third region 154. Accordingly, the third region 154 may be defined as a region for connection with the contact plug 155, and the contact plug 155 may be disposed outside a corresponding pixel region PA, thereby further reducing an influence on the floating diffusion region FD1 to FD4.

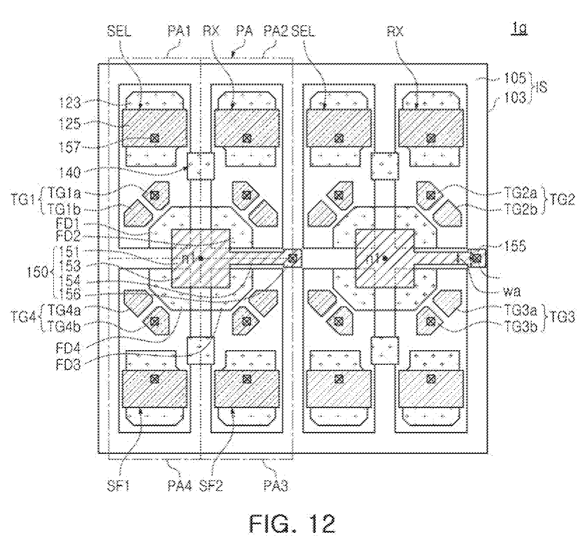

Referring to FIG. 12, an image sensor 1g is the same as FIGS. 3 to 5 except for the shape of the conductive structure 150.

The conductive structure 150 of the image sensor 1g of FIG. 12 may include a first region 151 and a second region 153, and may further include a third region 154 extending from the first region 151 within the element isolation region 105 and a fourth region 156 which is an end of the third region 154.

The third region 154 may extend along the element isolation region 105 from a portion of the side surface of the first region 151 that does not contact the second region 153, and may extend, for example, in the X-direction. In this case, the fourth region 156 may be disposed on the intersection n1 of the element isolation regions 105 which is an end of the third region 154. The third region 154 may extend in a bar shape, and the fourth region 156 is an extension portion having a width greater than the third region 154 in the Y-direction, and may have a square or circular shape. A width Wa in the Y-direction, which is perpendicular to the longitudinal direction of the third region 154, may be smaller than the width W2 of the element isolation region 105, and the fourth region 156 may have a width Wb that is greater than the third region 154 but smaller than the second width W2 of the element isolation region 105.

The contact plug 155 may be disposed in at least a portion of the fourth region 156. Accordingly, the fourth region 156 may be defined as a region for connection with the contact plug 155, and the contact plug 155 may be disposed outside the corresponding pixel region PA, so that the influence on the floating diffusion region FD1 to FD4 may be further reduced, and as the fourth region 156 has an extension portion, an electrical short circuit due to misalignment with the contact plug 155 may be minimized.

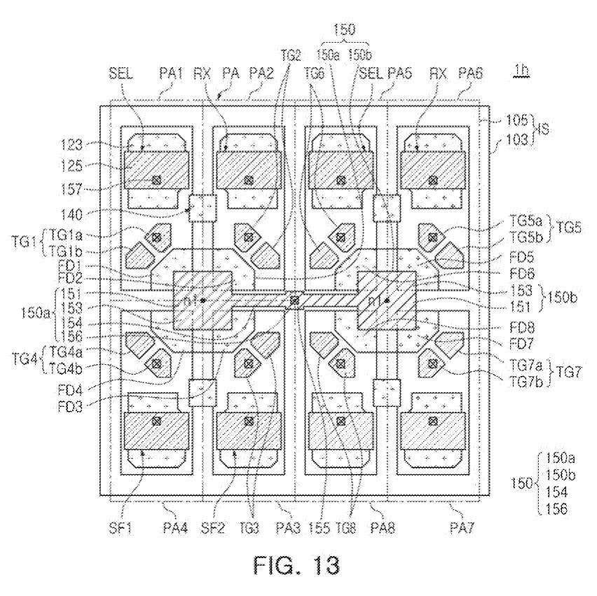

Referring to FIG. 13, an image sensor 1h is the same as FIGS. 3 to 5 except for the shape of the conductive structure 150.

The image sensor 1h of FIG. 13 may be divided into pixel regions PA in which two pixel regions PA of FIG. 3 correspond to one pixel. That is, in one pixel region PA, eight floating diffusion regions FD1 to FD8 may be synthesized to form one integrated floating diffusion region.

A first conductive structure 150a and a second conductive structure 150b connecting four diffusion regions FD1 to FD4 and a third region 154 that is a connection portion connecting the first conductive structure 150a and the second conductive structure 150b may form an integrated conductive structure 150.

Eight floating diffusion regions FD1, FD2, FD3, FD4, FD5, FD6, FD7, and FD8 may be electrically integrated by the integrated conductive structure 150.

In this manner, when eight sub-pixel regions PA1, PA2, PA3, PA4, PA5, PA6, PA7, and PA8 correspond to one pixel, some of the eight transistors disposed in each sub-pixel region PA1 to PA8 may be non-functional dummy transistors, but may be implemented in various ways depending on the circuit design.

In the integrated conductive structure 150, the third region 154 may be formed to have a bar shape extending along an interior of the element isolation region 105 to connect the first conductive structure 150a to a space between the first regions 151 of the second conductive structure 150b, and the third region 154 may pass through the intersection n1 of the element isolation region 105. The contact plug 155 may be disposed on the third region 154. Accordingly, the contact plug 155 may be disposed outside the sub-pixel region PA1 to PA8, so that the influence on the floating diffusion region FD1 to FD8 may be further reduced.

In this case, the third region 154 may further include a fourth region 156 that is an extension portion in which a width thereof increases in a region in contact with the contact plug 155, and as the third region 154 has the fourth region 156, an electrical short circuit due to misalignment with the contact plug 155 may be minimized.

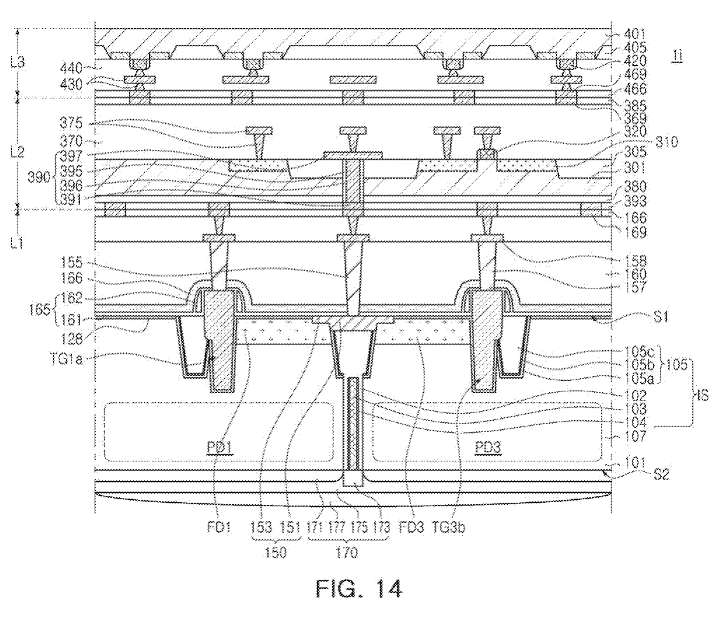

FIG. 14 illustrates a cross-section of an image sensor according to one or more embodiments.

Referring to FIG. 14, an image sensor 10i may include a third structure L3 forming a logic circuit 20, a second structure L2 formed below the third structure L3 and forming a pixel array 10, and a first structure L1 formed therebelow.

The image sensor 10i may include the first structure L1 including the first substrate 101, the second structure L2 including the second substrate 301, and the third structure L3 including the third substrate 401. The third structure L3 may be a logic chip including a logic circuit 20, and the second and first structures L1 and L2 may be image sensor structures including a plurality of pixels PX. The first structure L1 may include a transfer transistor TX, and the second structure L2 may include the remaining transistors except for the transfer transistors TX.

The first structure L1 includes the transfer gates TG1 to TG4, the floating diffusion regions FD1, FD2, FD3 and FD4 and the photodiodes PD1 to PD4, among the structures of the first substrate 101 described in FIGS. 1 to 5, and may include first bonding structures 166 and 169 in an upper portion thereof. The first structure L1 may include all of the optical portions 170 on the other surface of the first substrate 101, and the description thereof may be the same as that of FIG. 4.

The second structure L2 may include a second substrate 301 having a lower surface facing the first structure L1 and an upper surface opposite to the lower surface, an element isolation film 305 defining an active region ACT within the second substrate 301, circuit elements 320 on the upper surface of the second substrate 301, an interconnection region 375 connected to the circuit elements 320, second lower bonding structures 390 and 393 on the lower surface of the second substrate 301, a second upper bonding structure 385 on the upper surface of the second substrate 301, a second lower insulating layer 380 on the lower surface of the second substrate 301, and a second upper insulating layer 370 on the upper surface of the second substrate 301.

The second circuit elements 320 may be transistors excluding the transfer gates TG1 to TG4. The interconnection region 375 may be disposed between the second substrate 301 and the third structure L3. The interconnection region 375 may apply an electrical signal to the second circuit elements 320. A second upper bonding structure 285 may be a structure for bonding with the third structure L3. The second upper bonding structure 285 may include a metal material such as copper (Cu), but may be implemented as a bonding insulating layer, unlike this.

The second lower insulating layer 380 may include a bonding insulating layer 393 having a predetermined thickness from a lower surface thereof in the Z-direction. The bonding insulating layer 393 may be a layer for dielectric-to-dielectric bonding with the bonding insulating layer 166 of the first structure L1.

The second lower bonding structure 390 may be a structure for bonding with the first structure L1. The second lower bonding structure 390 may include a third bonding pad 391 on the lower surface of the second substrate 301, a landing structure 397 disposed on the upper surface of the second substrate 301, a third bonding via 395 disposed between the third bonding pad 391 and the landing structure 397, and a side insulating layer 396 between the second substrate 301 and the third bonding via 395. The third bonding pad 391 may include a metal material such as copper (Cu), and the third bonding via 395 may include a metal material such as copper (Cu), tungsten (W), and the like. The third bonding pad 391 may include the same metal material as the third bonding via 395, but embodiments are not limited thereto.

The third structure L3 may include a third substrate 401, and may include a third interconnection structure 430 connected to third circuit elements 420, a third bonding structure 440 on the third interconnection structure 430, and a logic insulating layer 443 covering and/or being provided on the third circuit elements 420 and the third interconnection structure 430 on the third substrate 401. The third bonding structure 440 may be connected to the third interconnection structure 430 on the third interconnection structure 430. The third bonding structure 440 may include a metal material such as copper (Cu). The third bonding structure 440 may also include a bonding pad to provide an electrical connection path. The logic insulation layer 443 may cover and/or be provided on the third circuit elements 420 and the third interconnection structure 430 and may simultaneously cover and/or be provided on a portion of the third bonding structure 440.

In this manner, an image sensor chip including the pixel array may be separated into two structures L1 and L2, and hybrid bonding may be performed between the structures L1 and L2 by the bonding structure 390, and the structures L1 and L2 may be electrically connected, thereby implementing an image sensor 1i by hybrid bonding of three structures L1, L2 and L3.

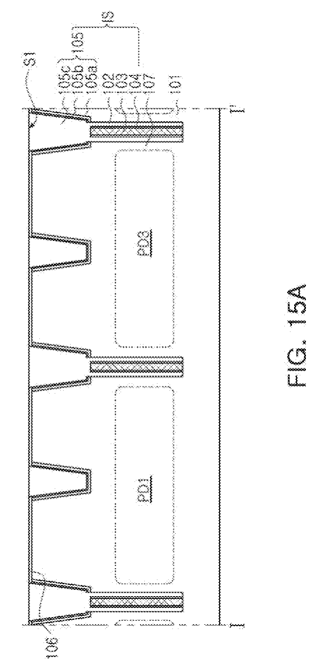

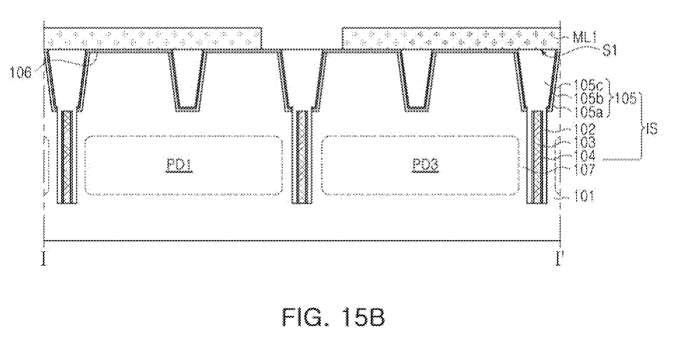

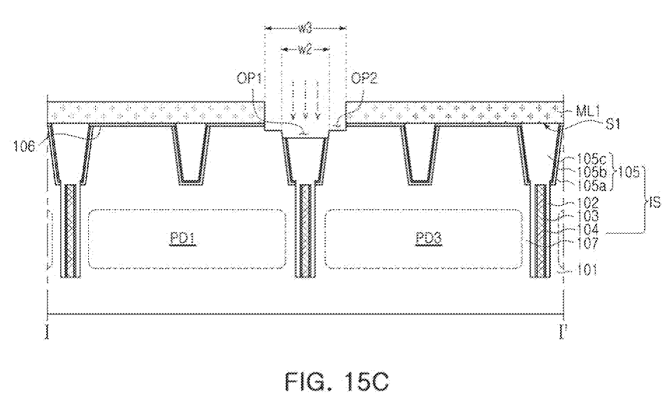

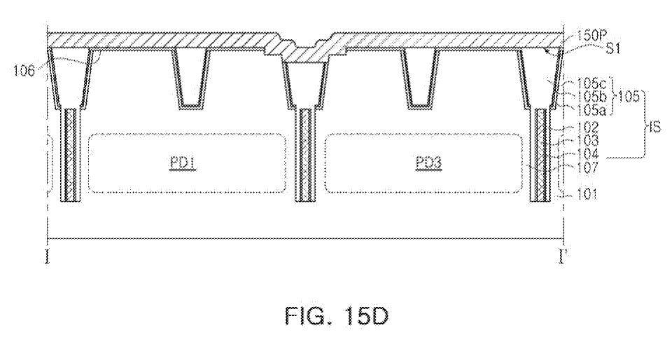

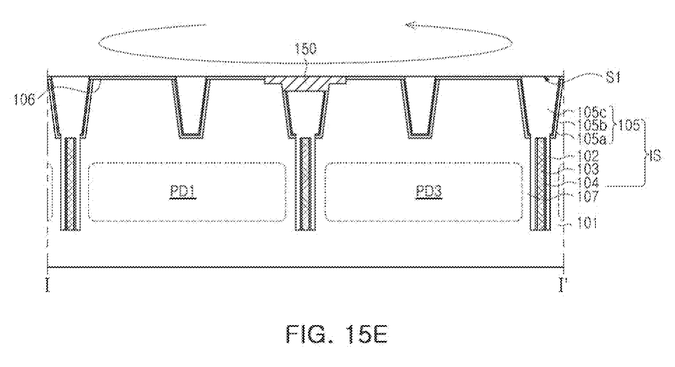

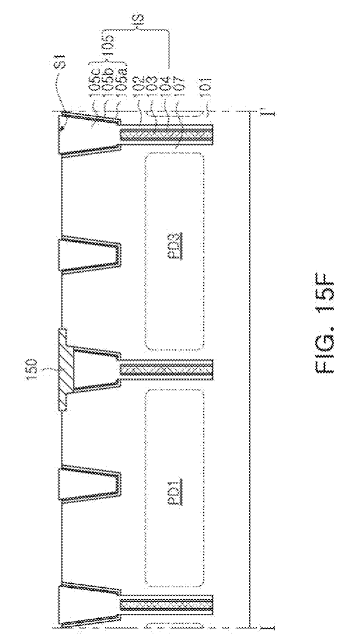

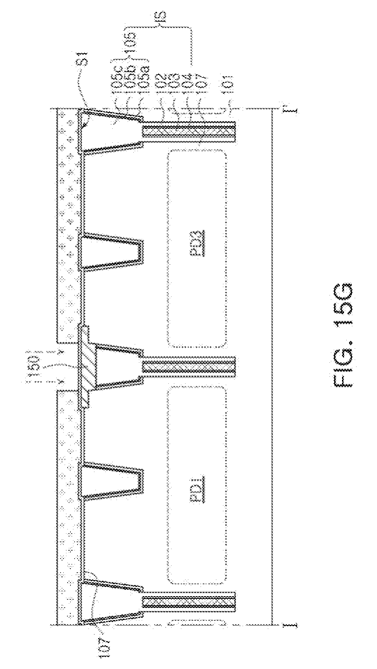

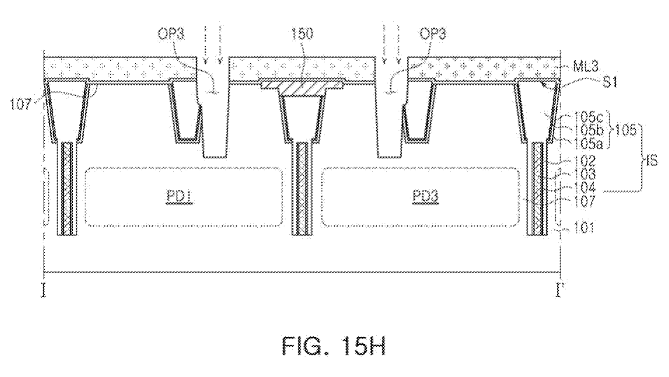

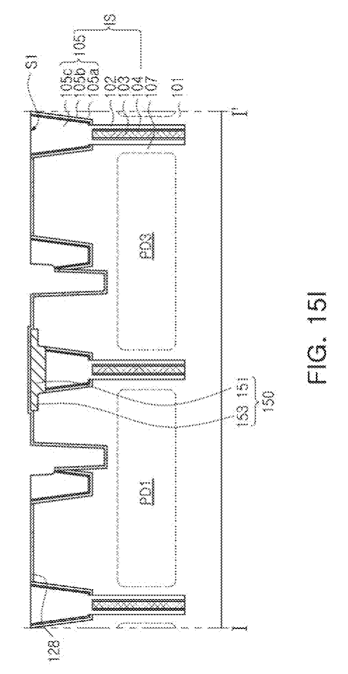

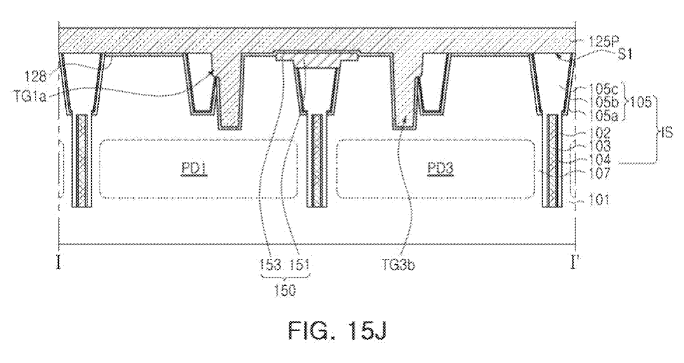

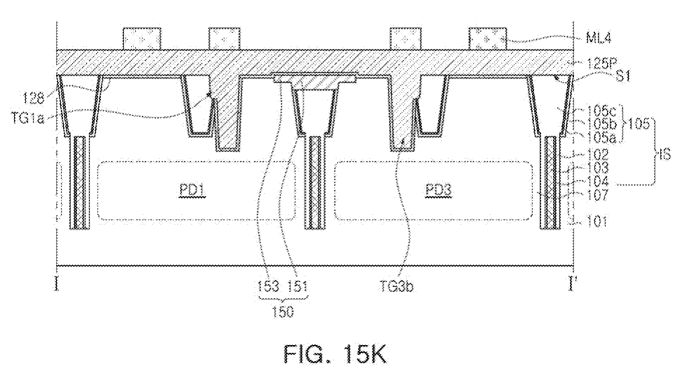

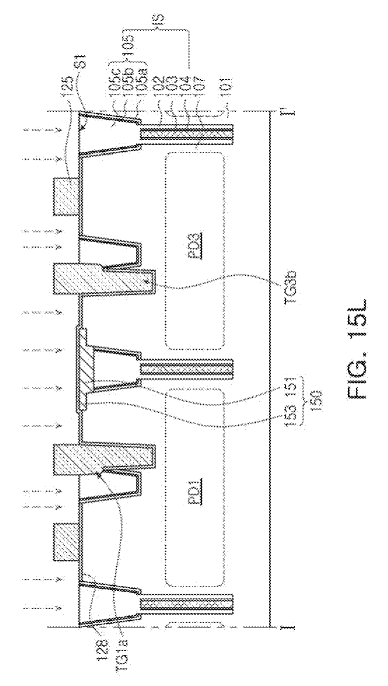

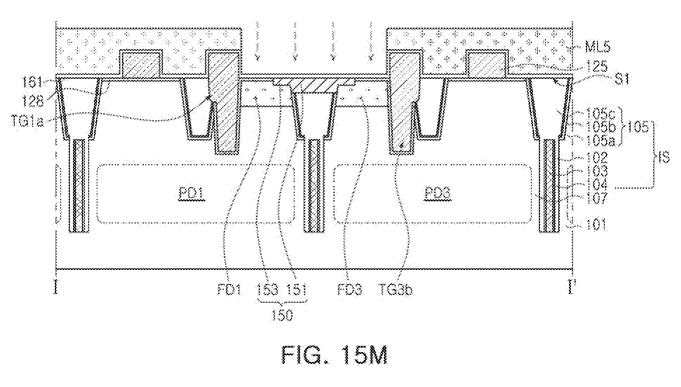

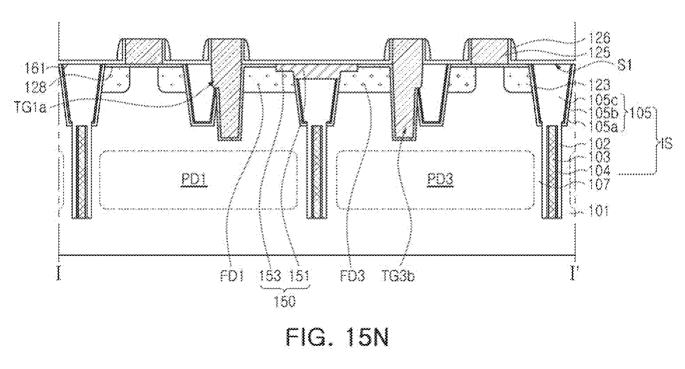

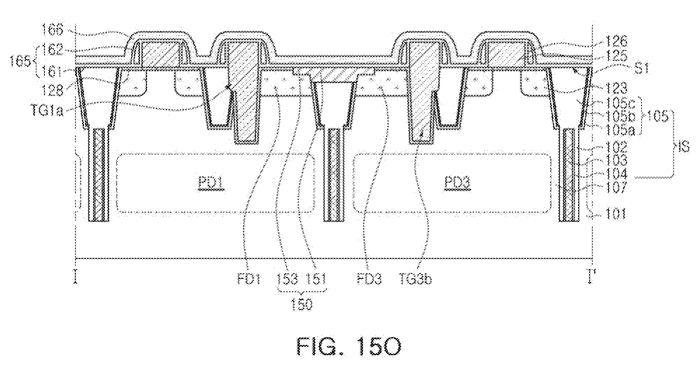

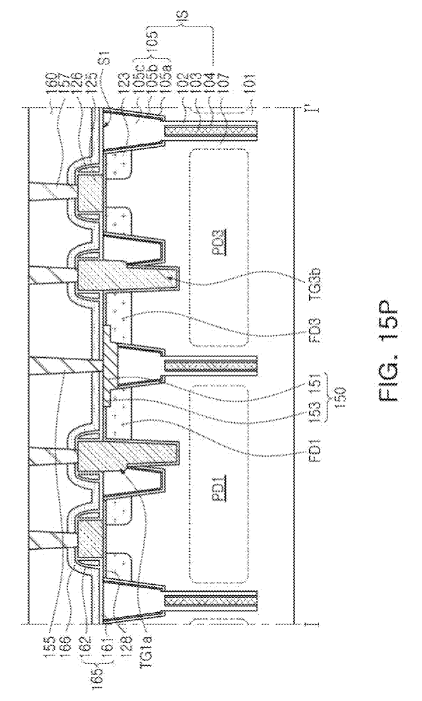

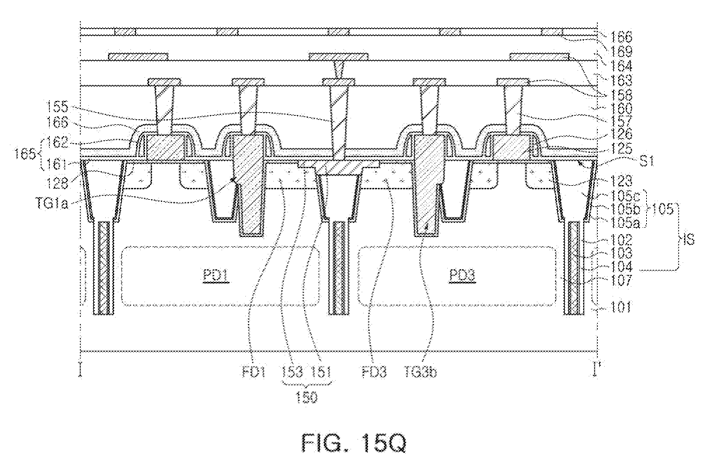

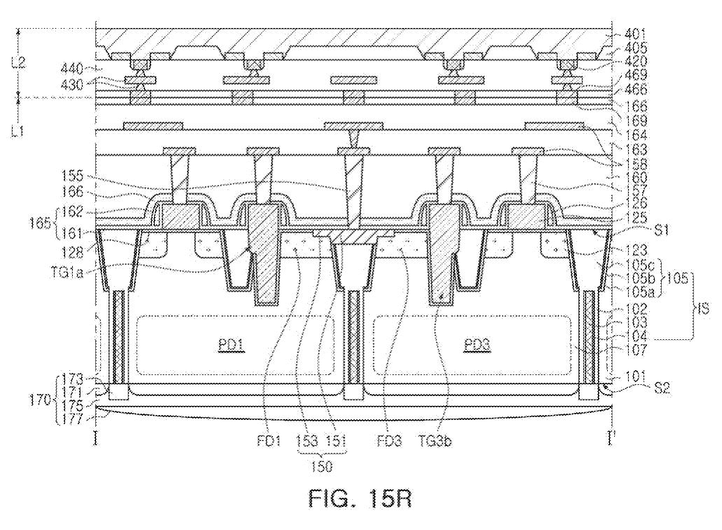

Hereinafter, a method of manufacturing an image sensor of one or more embodiments will be described with reference to FIGS. 15A to 15R. FIGS. 15A to 15R are cross-sectional views illustrating a method of manufacturing a pixel array of the image sensor 1 of FIG. 5.

Referring to FIG. 15A, a substrate 101 may be prepared, and an element isolation region 105 and a trench isolation film 103 may be formed from a first surface S1 of the substrate 101.

For example, photodiodes PD1 to PD4 may be formed within the substrate 101, and an element isolation region 105 defining the active region ACT may be formed on the first surface S1 of the substrate 101 by forming a trench and filling the trench. In this case, after forming an oxide film 105a on an inner wall of the trench, a nitride film may be formed as a liner 105b.

When forming the oxide film 105a and the liner 105b of the nitride film, the oxide film and the nitride film may be stacked on the first surface S1 of the substrate 101, and for example, a substrate liner 106 which is a nitride film may be formed on the first surface S1 of the substrate to have a greater thickness than a thickness the liner 105b of the element isolation region 105.

A portion of the liner 105b of the element isolation region 105 may be opened, and a deep trench for forming a trench isolation film 103 may be formed, and the deep trench may be formed in a grid shape to divide each sub-pixel region PA1 to PA4.

For example, after forming a deep trench from a lower surface of the element isolation region 105, a trench oxide film 102 and a trench liner 104 may be formed, and a trench isolation film 103 as a conductive material may be formed in a central portion. As the conductive material, polysilicon may be stacked. Next, the trench in the element isolation region 105 may be filled and an element isolation insulating film 105c may be formed.

In this case, the element isolation insulating film 105c may be over-deposited and may be then flattened until the substrate liner 106 is exposed, thereby forming the element isolation region 105.

Referring to FIG. 15B, a first mask pattern ML1 may be formed to expose the element isolation region 105 disposed on the intersection (center) n1 of four sub-pixel regions PA1 to PA4, i.e., the center n1 of the pixel region PA, and the surrounding substrate 101.

As illustrated in FIG. 15C, after forming a first opening OP1 corresponding to the first region 151 for the first mask pattern ML1, a second opening OP2 corresponding to the second region 153 may be continuously formed.

In this case, the first opening OP1 may be formed by etching the element isolation region 105 at a second width W2 and a second depth d2, and may have different depths depending on the interlayer etching selectivity of the element isolation region 105, but may be formed to uniformly have the second depth d2 in the Z direction.

Next, the second opening OP2 may be formed by etching the active region around the element isolation region 105 at a third depth d3 smaller than the second depth d2 in the Z-direction.

Accordingly, the first opening OP1 and the second opening OP2 may have a square shape having a third width W3 overall in the horizontal direction when viewed in a plan view, but including a region having a greater second depth d2 in a shape of a cross.

As illustrated in FIG. 15D, the first and second openings OP1 and OP2 may be filled by over-depositing a preliminary conductive structure 150P.

Cleaning may be performed to remove the first mask pattern ML1, and then a natural oxide film may be removed. In this case, the cleaning may be performed using, for example, an HF solution or dry cleaning. After cleaning, the first and second openings OP1 and OP2 may be filled with a conductive material, and the preliminary conductive structure 150P may be over-deposited to cover the first surface S1 of the substrate.

The preliminary conductive structure 150P may be formed by depositing polysilicon or epitaxially growing single crystal silicon. As another example, the preliminary conductive structure 150P may be formed by depositing a metal material.

As illustrated in FIG. 15E, the substrate liner 106 may be flattened with an etching stopper to form a conductive structure 150 filling the first and second openings OP1 and OP2. In this case, a flattening process may be chemical mechanical polishing (CMP) and etch-back may be performed, but embodiments are not limited thereto. According to this flattening process, upper surfaces of the first region 151 and the second region 153 of the conductive structure 150 may have a flat coplanar surface, and may have a coplanar surface with an upper surface of the substrate liner 106 and an upper surface of the element separation region 105.

Referring to FIG. 15F, the substrate liner 106 may be removed and cleaning may be performed. When a nitride film of the substrate liner 106 is removed using a phosphoric acid solution, the structure may be disposed on a level higher than a level of the substrate 101 by a predetermined height in the Z-direction, but embodiments are not limited thereto. According to one or more embodiments, the substrate liner 106 may remain and a subsequent process may be performed.

Referring to FIG. 15G, after forming a second mask pattern ML2 to restrictively open a central region of the conductive structure 150, for example, the central region of the first region 151, a first conductive type impurity of a second concentration may be ion-implanted into the central region of the conductive structure 150 opened by the second mask pattern ML2. For ion implantation, a surface oxide layer 108 may be formed before the second mask pattern ML2, and damage to the substrate 101 may be minimized through the surface oxide layer 108.

For example, as a first conductive type impurity, impurities such as P, As, and the like, may be implanted, and the second concentration may be greater than an impurity doping concentration for a subsequent floating diffusion region FD1 to FD4. For example, the second concentration may satisfy 1.0xe¹⁸ to 1.0xe²¹/cm³, but embodiments are not limited thereto.

Next, as in FIG. 15H, a third mask pattern ML3 for the transfer gates TG1 to TG4 may be formed.

The third mask pattern ML3 may be formed to open a region corresponding to the transfer gates TG1 to TG4, and the substrate 101 exposed through the third mask pattern ML3 may be removed to form a third opening OP3.

A depth of the third opening OP3 may vertically extend into the substrate 101 to a level closer to the photodiodes PD1 to PD4. Even in this case, after the third opening OP3 is formed, the damage may be removed by performing cleaning. Additionally, additional impurity doping may be performed in this case, but embodiments are not limited thereto.

Referring to FIG. 15I, a gate insulating layer 128 may be formed. Forming the gate insulating layer 128 may be formed by performing a cleaning process as a preprocessing to remove the surface oxide layer 108, and then depositing a silicon oxide film or the like as the gate insulating layer 128. In this case, the gate insulating layer 128 may be formed in the entire remaining region, apart from a region in which the transistors are formed, such as the element isolation region 105, of the first surface S1 of the substrate 101.

Referring to FIG. 15J, a conductive layer 125P may be formed by filling the third opening OP3.

In this case, the conductive layer 125P may be formed by stacking polysilicon, and the like, and may be formed by ion implantation after deposition of polysilicon, and the like, so as to have conductivity. In this case, the conductive layer 125P may be over-deposited on the entire surface S1 of the substrate 101 so that the conductive layers 125P of other transistors are also formed simultaneously.

As illustrated in FIG. 15K, a fourth mask pattern ML4 may be formed, and the conductive layer 125P may be patterned, so that the transfer gates TG1 to TG4 and the gate electrode layers 125 of other transistors may be formed simultaneously, as illustrated in FIG. 15l. In this case, a gate insulating layer 128 may remain in a lower portion of each gate electrode layer 125.

Next, as illustrated in FIG. 15M, impurity implantation may be performed to form floating diffusion regions FD1 to FD4.

First, after forming a fifth mask pattern ML5 opening each active region 123, a second conductive impurity may be ion-implanted at a first concentration to form a floating diffusion region FD1 to FD4.

Before the ion implantation, a surface of the gate electrode layer 125 may be oxidized, and the entire substrate 101 may be oxidized to form an insulating liner 161, and ions may be implanted through the insulating liner 161 to minimize damage to the substrate 101.

The insulating liner 161 may be removed from the conductive structure 150, but may remain and may be integrated with a subsequent gate insulating layer 128.

Referring to FIG. 15N, after forming a gate spacer 126, a second conductive impurity may be ion-implanted at a set concentration into each active region 123 to form a source and drain region 123. The gate spacer 126 may be formed by depositing silicon oxide or silicon nitride, and each source and drain region 123 may be formed by performing ion implantation according to various structures such as LDD, S/D, and the like. Additionally, a ground region 140 may also be formed by implanting impurities of different conductive types.

As illustrated in FIG. 15O, after forming the first upper insulating layer 162, annealing may be performed to advance activation, that is, diffusion, on each implanted impurity ion.

Additionally, after annealing, a nitride film, which is a second upper insulating layer 164, may be formed to protect the elements. In this case, the first upper insulating layer 162 and the second upper insulating layer 164 may be formed conformally according to the shape of each element. FIG. 15O illustrates that the gate insulating layer 128 is removed on the conductive structure 150 and the first upper insulating layer 162 is formed, but the gate insulating layer 128 may remain and the first upper insulating layer 162 may be formed thereon.

Next, as in FIG. 15P, after forming the interlayer insulating layer 160, contact plugs 155 and 157 penetrating through the interlayer insulating layer 160 and contacting each element may be formed.

The contact plugs 155 and 157 may be deposited and flattened to fill the metal layer after forming a via hole and then forming diffusion barriers 155a and 157a. The diffusion barriers 155a and 157a may be TiN, TaN, or the like, and the metal layer may include a conductive material such as W, Al, or Cu. The via holes may be formed to reach the gate electrode layer 125 and may be formed to open the first region 151 of the conductive structure 150.

Accordingly, the contact plug 155 may be formed to be spaced apart from the second region 153 of the conductive structure 150 and may be in contact with the first region 151, so that the contact plug 155 may be electrically connected while minimizing the influence on the floating diffusion region FD1 to FD4.

As illustrated in FIG. 15Q, upper interconnection structures 158 may be formed thereafter, and bonding structures 166 and 169 may be formed, and with reference to FIG. 15R, a second structure L2 may be formed in an upper portion, and an optical section 170 may be formed on the other surface S2 of the substrate 101, thereby forming the image sensor 1 of FIG. 4.

According to one or more embodiments, a conductive structure for electrical connection with a floating diffusion region may be formed by filling a portion of an element isolation region, so that damage to a lower floating diffusion region may be minimized during a via contact. Additionally, by including an extension portion in a portion of the floating diffusion region so that a portion of the conductive structure overlaps the floating diffusion region vertically, an electrical connection with the floating diffusion region may be induced.

Since the connection between the floating diffusion region and the conductive structure does not proceed in a region higher than the floating diffusion region in a vertical direction, unnecessary parasitic capacitance may be eliminated.

While embodiments have been described with reference to the figures, it will be understood by those of ordinary skill in the art that various changes in form and details may be made therein without departing from the spirit and scope as defined by the following claims and their equivalents.

What is claimed is:

1. An image sensor, comprising:
a substrate comprising pixel regions that comprise photoelectric conversion regions, respectively;
a floating diffusion region in a pixel region of the pixel regions, the floating diffusion region being configured to store charge transmitted from a photoelectric conversion region among the photoelectric conversion regions and being on a first surface of the substrate;
an element isolation region on the first surface of the substrate and adjacent to the floating diffusion region; and
a conductive structure protruding in a vertical direction from a first surface of the element isolation region and a first surface of the floating diffusion region toward a second surface of the element isolation region and a second surface of the floating diffusion region, and contacting the floating diffusion region and the element isolation region.

2. The image sensor of claim 1, wherein the conductive structure comprises:
a first region on at least a portion of the element isolation region and protruding in the vertical direction from the first surface of the element isolation region; and
a second region protruding in a horizontal direction from a side surface of the first region into the floating diffusion region and contacting the floating diffusion region.

3. The image sensor of claim 2, wherein a first surface of the first region and a first surface of the second region are coplanar.

4. The image sensor of claim 3, wherein a first length from the first surface of the first region to a second surface of the first region is greater than a second length from the first surface of the second region to a second surface of the second region.

5. The image sensor of claim 4, wherein a third length from the first surface of the floating diffusion region to a second surface of the floating diffusion region is greater than the first length.

6. The image sensor of claim 2, wherein the image sensor further comprises a contact plug electrically connected to the floating diffusion region, and
wherein the contact plug is in contact with a first surface of the first region of the conductive structure.

7. The image sensor of claim 6, wherein the contact plug is spaced apart from the second region of the conductive structure.

8. The image sensor of claim 1, wherein the conductive structure comprises a semiconductor material.

9. The image sensor of claim 8, wherein the floating diffusion region comprises a first conductivity type impurity in a first concentration, and
wherein the conductive structure comprises the first conductivity type impurity in a second concentration greater than the first concentration.

10. The image sensor of claim 2, wherein the conductive structure connects at least two floating diffusion regions in adjacent pixel regions among the pixel regions.

11. The image sensor of claim 10, wherein, floating diffusion regions in adjacent pixel regions among the pixel regions are symmetrical with respect to the element isolation region,
wherein the first region of the conductive structure is within the element isolation region, and
wherein the second region of the conductive structure is in the floating diffusion region of the pixel region of the pixel regions and symmetrical with respect to the element isolation region.

12. The image sensor of claim 2, wherein a second surface of the first region is parallel to the first surface of the first region.

13. The image sensor of claim 2, wherein a second surface of the first region comprises a bent portion.

14. An image sensor, comprising:
a substrate comprising pixel regions that comprise photoelectric conversion regions, respectively;
a trench isolation region defining the pixel regions within the substrate;
a floating diffusion region adjacent to the trench isolation region in a pixel region of the pixel regions, the floating diffusion region being configured to store charges transmitted from the photoelectric conversion region and being on a first surface of the substrate;
an element isolation region on the trench isolation region that is on the first surface of the substrate and in contact with the floating diffusion region; and
a conductive structure expanded from the element isolation region, and in contact with at least two floating diffusion regions in two adjacent pixel regions of the pixel regions,
wherein a first surface of the conductive structure is coplanar with a first surface of the element isolation region and protrudes in a vertical direction into the element isolation region and the at least two floating diffusion regions.

15. The image sensor of claim 14, wherein the conductive structure comprises:
a first region on at least a portion of the element isolation region and protruding in the vertical direction from the first surface of the element isolation region; and
second regions respectively protruding in a horizontal direction from side surfaces of the first region to the at least two floating diffusion regions and respectively contacting the at least two floating diffusion regions.

16. The image sensor of claim 15, wherein the conductive structure comprises four second regions in contact with four floating diffusion regions of four pixel regions in a 2x2 array, and
wherein the first region is on an intersection of the four pixel regions in the 2x2 array.

17. The image sensor of claim 16, wherein the four floating diffusion regions are symmetrical with respect to the intersection of the pixel regions, and
wherein the first region has a cross shape passing through the intersection.

18. The image sensor of claim 17, wherein the image sensor further comprises a contact plug electrically connected to the four floating diffusion regions,
wherein the contact plug is in contact with a first surface of the first region of the conductive structure and is spaced apart from the second regions.

19. The image sensor of claim 17, wherein the image sensor further comprises a connecting portion extending from the first region of the conductive structure and connected to the first region of the conductive structure.

20. An image sensor, comprising:
a pixel array comprising a plurality of pixel regions on a first surface of a substrate, a pixel region of the plurality of pixel regions comprising a photodiode and a color filter on a second surface of the substrate, opposite to the first surface; and
a logic circuit configured to obtain a pixel signal from the plurality of pixel regions,
wherein the pixel array comprises:
a floating diffusion region in a pixel region of the plurality of pixel regions, the floating diffusion region being configured to store charges transmitted from the photodiode and being on the first surface of the substrate;
an element isolation region adjacent to the floating diffusion region; and
a conductive structure protruding in a vertical direction from a first surface of the element isolation region and a first surface of the floating diffusion region toward a second surface of the element isolation region and a second surface of the floating diffusion region, and contacting the floating diffusion region and the element isolation region.
